(19) United States
(12) Patent Application Publication
(10) Pub. No.: US 2026/0059908 A1
(43) Pub. Date: Feb. 26, 2026

(54) DISPLAY PANEL AND DISPLAY APPARATUS

(71) Applicant: Tianma Advanced Display Technology Institute (Xiamen) Co., Ltd., Xiamen (CN)

(72) Inventors: Wenqi ZHOU, Xiamen (CN); Sitao HUO, Xiamen (CN); Tianyi WU, Xiamen (CN)

(73) Assignee: Tianma Advanced Display Technology Institue (Xiamen) Co., Ltd., Xiamen (CN)

(21) Appl. No.: 18/946,994

(22) Filed: Nov. 14, 2024

(30) Foreign Application Priority Data
Aug. 23, 2024 (CN) 202411168540.0

(51) Int. Cl. H01L 33/58; H01L 25/075; H01L 25/16; H01L 33/20; H01L 33/52; H01L 33/62

(52) U.S. Cl. CPC H10H 20/855; H01L 25/0753; H01L 25/167; H10H 20/819; H10H 20/857; H10H 20/852

(57) ABSTRACT

The present application provides a display panel and a display apparatus. The embodiments of the present application provide a display panel, where the display panel includes an array substrate, a light-emitting element, and a light-shielding layer. The light-emitting element is located on one side of the array substrate and is electrically connected to the array substrate. A plurality of light-emitting elements include a first light-emitting element and a second light-emitting element with different colors. The first light-emitting element has a first light-emitting surface facing away from the array substrate, and the second light-emitting element has a second light-emitting surface facing away from the array substrate. The light-shielding layer is arranged on one side of the array substrate.

### CROSS-REFERENCE TO RELATED APPLICATIONS

This application claims priority to Chinese Patent Application No. 202411168540.0, titled “DISPLAY PANEL AND DISPLAY APPARATUS” and filed on Aug. 23, 2024, which is hereby incorporated by reference in its entirety.

### TECHNICAL FIELD

The present application relates to the technical field of display devices, and in particular to a display panel and a display apparatus.

### BACKGROUND

With the development of display technology, display products are showing a diversified development trend. Micro-light-emitting elements are increasingly used in display products due to their advantages of high brightness, high contrast and high reliability. When a display apparatus with micro-light-emitting elements is displayed, the contrast of the displayed image decreases due to the presence of ambient light and the high reflectivity of the metal routing lines in the light-emitting elements and the backplane, affecting the user's viewing experience.

In related technologies, in order to reduce the reflection of light by metal routing lines, the light-shielding materials are generally used to block the metal routing lines. However, due to the problem of light-shielding materials remaining on the light-emitting surface of the light-emitting elements, the light extraction efficiency of the light-emitting element is affected.

### SUMMARY

The embodiments of the present application provide a display panel and a display apparatus, which can improve the reliability of the display panel.

In a first aspect, an embodiment of the present application provides a display panel, the display panel includes an array substrate, a light-emitting element and a light-shielding layer, the light-emitting element is located on one side of the array substrate and is electrically connected to the array substrate, and a plurality of the light-emitting elements include a first light-emitting element and a second light-emitting element with different colors, the first light-emitting element has a first light-emitting surface facing away from the array substrate, and the second light-emitting element has a second light-emitting surface facing away from the array substrate.

The light-shielding layer is arranged on one side of the array substrate, and in a direction parallel to the plane where the array substrate is located, the light-shielding layer includes a first light-shielding portion arranged adjacent to the first light-emitting element and a second light-shielding portion arranged adjacent to the second light-emitting element, where in a thickness direction of the array substrate, a distance between a plane where the first light-emitting surface is located and the first light-shielding portion is greater than a distance between the second light-emitting surface and the second light-shielding portion.

In a second aspect, an embodiment of the present application provides a display panel, the display panel includes an array substrate, a light-emitting element and a light-shielding layer, the light-emitting element is located on one side of the array substrate and is electrically connected to the array substrate, and a plurality of the light-emitting elements include a first light-emitting element, a second light-emitting element and a third light-emitting element arranged adjacently one another. The light-shielding layer is arranged on one side of the array substrate, and at least partially located between adjacent of the light-emitting elements, where a distance between the first light-emitting element and the second light-emitting element adjacent to each other is greater than a distance between the second light-emitting element and the third light-emitting element adjacent to each other.

In a third aspect, an embodiment of the present application provides a display apparatus, and the display apparatus includes a display panel in any of the aforementioned embodiments.

### BRIEF DESCRIPTION OF THE DRAWINGS

In order to more clearly illustrate the technical solution of the embodiments of the present application, the drawings required for use will be introduced briefly in the embodiments of the present application below. Those skilled in the art may also obtain other drawings based on these drawings without creative work.

FIG. 1 is a schematic structural diagram of a partial top view of a display panel provided in an embodiment of the present application;

FIG. 2 is a schematic structural cross-sectional view at A-A in FIG. 1;

FIG. 3 is a schematic structural diagram of a partial cross-section of the display panel provided in an embodiment of the present application;

FIG. 4 is a schematic structural diagram of another partial cross-section of the display panel provided in an embodiment of the present application;

FIG. 5 is a schematic structural diagram of another partial cross-section of the display panel provided in an embodiment of the present application;

FIG. 6 is a schematic structural diagram of another partial cross-section of the display panel provided in an embodiment of the present application;

FIG. 7 is a schematic structural diagram of another partial cross-section of the display panel provided in an embodiment of the present application;

FIG. 8 is a schematic structural diagram of another partial cross-section of the display panel provided in an embodiment of the present application;

FIG. 9 is a schematic structural diagram of another partial cross-section of the display panel provided in an embodiment of the present application;

FIG. 10 is a schematic structural diagram of another partial top view of the display panel provided in an embodiment of the present application;

FIG. 11 is a schematic structural diagram of another partial top view of the display panel provided in an embodiment of the present application;

FIG. 12 is a schematic structural diagram of another partial cross-section of the display panel provided in an embodiment of the present application;

FIG. 13 is a schematic structural diagram of another partial top view of the display panel provided in an embodiment of the present application;

FIG. 14 is a schematic structural diagram of another partial top view of the display panel provided in an embodiment of the present application;

FIG. 15 is a schematic structural diagram of another top view of the display panel provided in an embodiment of the present application;

FIG. 16 is a schematic structural diagram of another partial cross-section of the display panel provided in an embodiment of the present application;

FIG. 17 is a schematic structural diagram of another partial cross-section of the display panel provided in an embodiment of the present application;

FIG. 18 is a schematic structural diagram of another partial cross-section of the display panel provided in an embodiment of the present application; and

FIG. 19 is a schematic structural diagram of a display apparatus provided in an embodiment of the present application.

### REFERENCE NUMBERS

100, display panel; 200, display apparatus;
10, array substrate; 11, convex portion; 12, concave portion; 13, first bonding pad; 14, second bonding pad; 15, first signal line;
20, light-emitting element; 21, first light-emitting element; 211, first epitaxial structure; 212, first electrode structure; 213, first light-emitting body; 214, first light-transmitting portion; 22, second light-emitting element; 221, second epitaxial structure; 222, second electrode structure; 223, second light-emitting body; 224, second light-transmitting portion; 23, third light-emitting element;
30, light-shielding layer; 31, first light-shielding portion; 32, second light-shielding portion; 33, third light-shielding portion; 34, first light-shielding material portion; 35, second light-shielding material portion;
50, transparent adhesive layer;
60, inorganic layer;
F, repeating unit;
A1, first area; A2, second area; A3, first central area; A4, first edge area; A5, second central area; A6, second edge area; A7, transparent area;
O1, center of first area; O2, center of second area; O3, center of display panel;
M1, first surface; M2, second surface;
C1, first light-emitting surface; C2, second light-emitting surface; C3, third light-emitting surface;
X, first direction; Y, second direction; Z, thickness direction of array substrate.

### DETAILED DESCRIPTION

The features and exemplary embodiments of various aspects of the present application will be described in detail below. In order to make the purpose, technical solutions and advantages of the present application clearer, the present application will be further described in detail below in conjunction with the drawings and specific embodiments. It should be understood that the specific embodiments described herein are only intended to explain the present application, rather than to limit the present application. For those skilled in the art, the present application can be implemented without the need for some of these specific details. The following description of the embodiments is only to provide a better understanding of the present application by illustrating the examples of the present application.

It should be noted that, in the present application, relational terms such as first and second, etc. are only used to distinguish one entity or operation from another entity or operation, and do not necessarily require or imply that there is any such actual relationship or order between these entities or operations. Moreover, the terms “include”, “comprise” or any other variant thereof are intended to cover non-exclusive inclusion, so that a process, method, article or device including a series of elements includes not only those elements, but also other elements that are not explicitly listed, or includes elements inherent to such a process, method, article or device. In the absence of further restrictions, the elements defined by the sentence “include . . .” do not exclude the existence of other identical elements in the process, method, article or device including the elements.

In the related art, the preparation process of the light-shielding material is generally after the light-emitting element is transferred to the driving substrate. Specifically, the light-emitting element is first transferred to the driving substrate, and then a whole layer of light-shielding layer is prepared on a surface of one side of the driving substrate facing the light-emitting element. The light-shielding layer can cover the metal routing lines in the driving substrate to reduce the reflection of light by the metal routing lines, but part of the materials in the light-shielding layer may usually remain on the light-emitting surface of the light-emitting element, thereby affecting the light extraction efficiency of the light-emitting element.

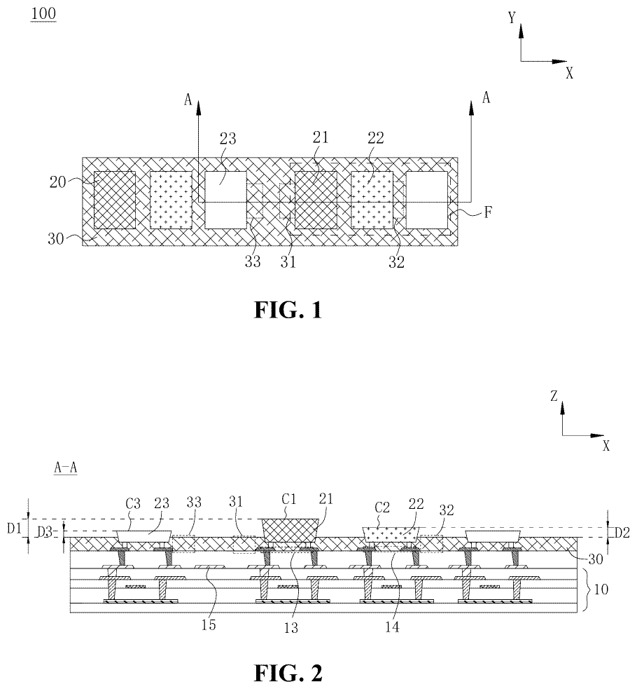

In view of the above-mentioned problems, in a first aspect, referring to FIG. 1 to FIG. 3. The embodiments of the present application provide a display panel 100. The display panel 100 includes an array substrate 10, a light-emitting element 20 and a light-shielding layer 30. The light-emitting element 20 is located on one side of the array substrate 10 and is electrically connected to the array substrate 10. A plurality of the light-emitting elements 20 include first light-emitting element 21 and second light-emitting element 22 with different colors. The first light-emitting element 21 has a first light-emitting surface C1 facing away from the array substrate 10, and the second light-emitting element 22 has a second light-emitting surface C2 facing away from the array substrate 10.

The light-shielding layer 30 is arranged on one side of the array substrate 10. In a direction parallel to a plane where the array substrate 10 is located, the light-shielding layer 30 includes a first light-shielding portion 31 adjacent to the first light-emitting element 21 and a second light-shielding portion 32 adjacent to the second light-emitting element 22. In a thickness direction Z of the array substrate 10, a distance D1 between a plane where the first light-emitting surface C1 is located and the first light-shielding portion 31 is greater than a distance D2 between the second light-emitting surface C2 and the second light-shielding portion 32.

The array substrate 10 is a module structure in the display panel 100 for driving and controlling the light-emitting element 20 to realize light-emitting display. The array substrate 10 may include a substrate and a driving layer arranged on one side of the substrate. The substrate may be in a rigid structure or a flexible structure, which is not limited in the embodiments of the present application. The specific structure of the driving layer may be arranged according to actual needs. Exemplarily, the driving layer may include a conductor layer, a semiconductor layer and an insulating layer that are stacked, with the insulating layer being located between adjacent two of the conductor layers or between adjacent of the conductor layer and the semiconductor layer.

The light-emitting element 20 may be a micro light-emitting element 20 such as a micro light-emitting diode (Micro Light Emitting LioLe, Micro LEL) or a sub-millimeter light-emitting diode (Mini Light Emitting LioLe, Mini LEL). The light-emitting element 20 is arranged on one side of the array substrate 10, where the light-emitting element 20 may have a variety of structural forms, for example, the light-emitting element 20 may be a flip chip, or a wire-bonding chip, or a vertical chip, which is not limited in the embodiments of the present application.

A plurality of light-emitting elements 20 include first light-emitting element 21 and second light-emitting element 22 with different colors. In other words, the first light-emitting element 21 and the second light-emitting element 22 are used to emit light of different colors respectively. The first light-emitting element 21 and the second light-emitting element 22 may be two light-emitting elements 20 arranged adjacent to each other, that is, there may be no other light-emitting element 20 between the first light-emitting element 21 and the second light-emitting element 22 that are closest to each other, or the first light-emitting element 21 and the second light-emitting element 22 may also be two light-emitting elements 20 arranged non-adjacently, that is, there may be other light-emitting elements 20 between the first light-emitting element 21 and the second light-emitting element 22 that are closest to each other.

The first light-emitting element 21 has a first light-emitting surface C1, the first light-emitting surface C1 is a light-emitting surface on the first light-emitting element 21. Exemplarily, the first light-emitting element 21 may include a first epitaxial structure 211, the first epitaxial structure 211 is a multilayer crystal film layer structure formed in the first light-emitting element 21 through a specific chemical or physical process. On this basis, the first light-emitting surface C1 may be a surface of one side of the first epitaxial structure 211 facing away from the array substrate 10, or when the first light-emitting element 21 also includes other auxiliary film layer structures located on one side of the first epitaxial structure 211 facing away from the array substrate 10, the first light-emitting surface C1 may be located on one side of the auxiliary film layer structure facing away from the array substrate 10 and spaced apart from the first epitaxial structure 211 in a thickness direction Z of the array substrate 10. The second light-emitting element 22 has a second light-emitting surface C2, the second light-emitting surface C2 is similar to the first light-emitting surface C1, which is not repeated in the embodiments of the present application.

The light-shielding layer 30 is a film layer including a light-shielding material, and the light-shielding layer 30 and the light-emitting element 20 are formed on the same side of the array substrate 10, and the light-shielding layer 30 is formed after the light-emitting element 20, that is, the light-emitting element 20 is first transferred to the driving substrate, and then the light-shielding layer 30 is prepared. The light-shielding layer 30 includes a first light-shielding portion 31 and a second light-shielding portion 32. The first light-shielding portion 31 is a partial structure of the light-shielding layer 30 located on a periphery of the first light-emitting element 21 and can contact a side surface of the first light-emitting element 21. The second light-shielding portion 32 is a partial structure of the light-shielding layer 30 located on a periphery of the second light-emitting element 22 and can contact a side surface of the second light-emitting element 22.

A position of the first light-shielding portion 31 relative to the first light-emitting element 21 and a position of the second light-shielding portion 32 relative to the second light-emitting element 22 may be the same, or different. Exemplarily, taking the first light-shielding portion 31 being located on one side of the first light-emitting element 21 along a first direction X as an example, the second light-shielding portion 32 may be located on one side of the second light-emitting element 22 along the first direction X, or may be located on one side of the second light-emitting element 22 along the second direction Y, where the first direction X and the second direction Y are both parallel to the plane where the array substrate 10 is located and intersect with each other. Further, the first light-emitting element 21 and the second light-emitting element 22 have opposite sides in the first direction X. On this basis, when the second light-shielding portion 32 is located on one side of the second light-emitting element 22 along the first direction X, the first light-shielding portion 31 and the second light-shielding portion 32 may be located on the same side of the first light-emitting element 21 and the second light-emitting element 22, respectively, or may be located on different sides of the first light-emitting element 21 and the second light-emitting element 22, respectively.

In addition, a relationship between the first light-shielding portion 31 and the second light-shielding portion 32 is also not limited in the embodiments of the present application. Exemplarily, the first light-shielding portion 31 may be spaced apart from the second light-shielding portion 32, or the first light-shielding portion 31 and the second light-shielding portion 32 may be connected and integrally arranged. Herein, three light-emitting elements 20 with different luminous colors are illustrated in FIG. 1 and FIG. 2 by means of numbers, and the light-shielding portions corresponding to the three light-emitting elements 20 are shown by means of dotted boxes.

The formation method of the light-shielding layer 30 is not limited in the embodiments of the present application. Optionally, the light-shielding layer 30 may be formed by thermoplastic molding. Specifically, the light-shielding layer 30 includes a thermoplastic light-shielding material. During the preparation process, if the temperature of the light-shielding layer 30 is greater than or equal to the melting point of the thermoplastic light-shielding material, the light-shielding layer 30 may melt into a liquid state, and the thermoplastic light-shielding material in the liquid state may flow and deform on the light-emitting element 20 and between adjacent light-emitting elements 20. If the temperature of the light-shielding layer 30 is less than the melting point of the thermoplastic light-shielding material, the light-shielding layer 30 may solidify into a solid state when cooled, and most of the thermoplastic light-shielding material in the solid state may be filled between adjacent light-emitting elements 20 to meet the normal working needs of the display panel 100. In the process of thermoplastic molding, part of the materials corresponding to the light-shielding layer 30 may remain on the light-emitting surface of the light-emitting element 20, thereby reducing the light extraction efficiency of the corresponding light-emitting element 20.

Alternatively, in another embodiment, the light-shielding layer 30 may also be formed by printing a black light-shielding material. Herein, when printing the black light-shielding material, the black light-shielding material may infiltrate and diffuse along a side surface of the light-emitting element 20 to the light-emitting surface of the light-emitting element 20, which is also likely to reduce the light extraction efficiency of the light-emitting element 20.

On this basis, whether the light-shielding layer 30 is formed by thermoplastic molding or printing, it is prone to cause the light-shielding material to remain on the first light-emitting surface C1 corresponding to the first light-emitting element 21, thereby reducing the light extraction efficiency of the first light-emitting element 21. In view of this, the structure of display panel 100 at the first light-emitting element 21 is adjusted in the embodiments of the present application to reduce the residual light-shielding material on the first light-emitting element 21.

Specifically, in the thickness direction Z of the array substrate 10, a distance D1 between the plane where the first light-emitting surface C1 is located and the first light-shielding portion 31 is greater than a distance D2 between the second light-emitting surface C2 and the second light-shielding portion 32. Considering that an upper surface of the first light-shielding portion 31 may not be a flat surface, the “distance between the plane where the first light-emitting surface C1 is located and the first light-shielding portion 31” mentioned here refers to: an average distance between the plane where the first light-emitting surface C1 is located and the upper surface of the first light-shielding portion 31. The distance between the second light-emitting surface C2 and the second light-shielding portion 32 is similar, which is not repeated in the embodiments of the present application.

A height difference between the first light-emitting surface C1 and the first light-shielding portion 31 is greater than a height difference between the second light-emitting surface C2 and the second light-shielding portion 32. Generally, the greater the height difference, the more likely it is for the fluid to flow downward. Therefore, during the preparation of the light-shielding layer 30, due to the relatively large height difference between the first light-emitting surface C1 and the first light-shielding portion 31, it is more likely for the light-shielding material remaining on the first light-emitting surface C1 to flow downward to a periphery of the first light-emitting element 21, which is conducive to reducing the influence of the light-shielding material on the light extraction efficiency of the first light-emitting element 21.

It should be noted that a large height difference can be made between the first light-emitting surface C1 and the first light-shielding portion 31 in a variety of ways. For example, the first light-emitting element 21 can be heightened during the preparation of the first light-emitting element 21, so that in the thickness direction Z of the array substrate 10, the size of the first light-emitting element 21 is larger than the size of the second light-emitting element 22. In this way, the plane where the first light-emitting surface C1 is located may be located on one side of the plane where the second light-emitting surface C2 is located facing away from the array substrate 10, thereby meeting the need for a large height difference between the first light-emitting surface C1 and the first light-shielding portion 31.

Alternatively, in some other embodiments, the structures of the array substrate 10 at different positions may be designed differently. For example, part of structures of the array substrate 10 at the first light-emitting element 21 may be thickened so that the plane where the first light-emitting surface C1 is located is thickened to one side of the plane where the second light-emitting surface C2 is located facing away from the array substrate 10. Alternatively, the part of structures of the array substrate 10 at a periphery of the first light-emitting element 21 may be concave downward so that the plane where the formed upper surface of the first light-shielding portion 31 is located is located on one side of the plane where the upper surface of the second light-shielding portion 32 is located close to the array substrate 10, which can also meet the need for a larger height difference between the first light-emitting surface C1 and the first light-shielding portion 31.

In summary, in the embodiments of the present application, the structure of the display panel 100 at the first light-emitting element 21 is adjusted, and the height difference between the first light-emitting surface C1 and the first light-shielding portion 31 is set to be greater than the height difference between the second light-emitting surface C2 and the second light-shielding portion 32, so that the light-shielding material remaining on the first light-emitting surface C1 is more likely to flow downward to the peripheral side of the first light-emitting element 21, thereby reducing the light-shielding residue at the first light-emitting surface C1, which is conducive to improving the light extraction efficiency corresponding to the first light-emitting element 21, reducing the brightness difference between the first light-emitting element 21 and the second light-emitting element 22, and improving the display uniformity and display effect.

The specific luminous colors of the first light-emitting element 21 and the second light-emitting element 22 are not limited in the embodiments of the present application. Optionally, under a premise of the same size of light-shielding material residue, the adverse effect on the light extraction efficiency of the first light-emitting element 21 is greater than the adverse effect on the light extraction efficiency of the second light-emitting element 22. In other words, with respect to the second light-emitting element 22, the light extraction efficiency corresponding to the first light-emitting element 21 is more likely affected by the light-shielding material, thereby causing the problem of uneven display. Further, under the shielding effect of the light-shielding materials with the same size, the light extraction efficiency corresponding to the first light-emitting element 21 is less than the light extraction efficiency corresponding to the second light-emitting element 22. In this case, the design in the embodiments of the present application is conducive to reducing the risk of uneven display caused by the different light-emitting efficiencies of the first light-emitting element 21 and the second light-emitting element 22, and improving the display accuracy and effect of the display panel 100.

In addition, whether there is any light-shielding material remaining on the first light-emitting surface C1 is not limited in the embodiments of the present application. Exemplarily, since there is a large height difference between the first light-emitting surface C1 and the first light-shielding portion 31, all the light-shielding materials on the first light-emitting surface C1 may flow to the periphery of the first light-emitting element 21, that is, no light-shielding material remains on the first light-emitting surface C1, or a small amount of light-shielding material may remain on the first light-emitting surface C1. Further, whether there is any light-shielding material remaining on the second light-emitting surface C2 is not limited in the embodiments of the present application.

In some embodiments, as shown in FIG. 1 to FIG. 3, the plane where the first light-emitting surface C1 is located is located on the side of the plane where the second light-emitting surface C2 is located facing away from the array substrate 10.

In combination with the foregoing content, it can be known that the adjustment of the position of the first light-emitting surface C1 can be achieved in a variety of ways, for example, the structure of the first light-emitting element 21 can be adjusted so that the size of the first light-emitting element 21 is larger than the size of the second light-emitting element 22 in the thickness direction Z of the array substrate 10. In this way, the plane where the first light-emitting surface C1 is located may be located on one side of the plane where the second light-emitting surface C2 is located facing away from the array substrate 10. Further, a new film layer structure can be added to the first light-emitting element 21 to meet the size requirements of the first light-emitting element 21, or the film layer structure existing in the first light-emitting element 21 can be thickened to meet the size requirements of the first light-emitting element 21.

Alternatively, part of structures of the array substrate 10 at the first light-emitting element 21 can also be thickened so that the plane where the first light-emitting surface C1 is located is thickened to one side of the plane where the second light-emitting surface C2 is located facing away from the array substrate 10. Furthermore, a new film layer structure may be added to the array substrate 10, and in the thickness direction Z of the array substrate 10, the newly added film layer structure overlaps the first light-emitting element 21 to meet the need to increase the height of the first light-emitting surface C1. Alternatively, the film layer structure existing in the array substrate 10 may be thickened, and the thickened position may be arranged corresponding to the first light-emitting element 21, so as to also meet the need to increase the height of the first light-emitting surface C1.

In the embodiments of the present application, the plane where the first light-emitting surface C1 is located is not the same plane as the plane where the second light-emitting surface C2 is located. By disposing the plane where the first light-emitting surface C1 is located on one side of the plane where the second light-emitting surface C2 is located facing away from the array substrate 10, it is conducive to achieving that the height difference between the first light-emitting surface C1 and the first light-shielding portion 31 is greater than the height difference between the second light-emitting surface C2 and the second light-shielding portion 32, thereby increasing the probability of the light-shielding material at the first light-emitting surface C1 flowing downward, reducing the brightness difference between the first light-emitting element 21 and the second light-emitting element 22, which is conducive to improving display uniformity and display effect.

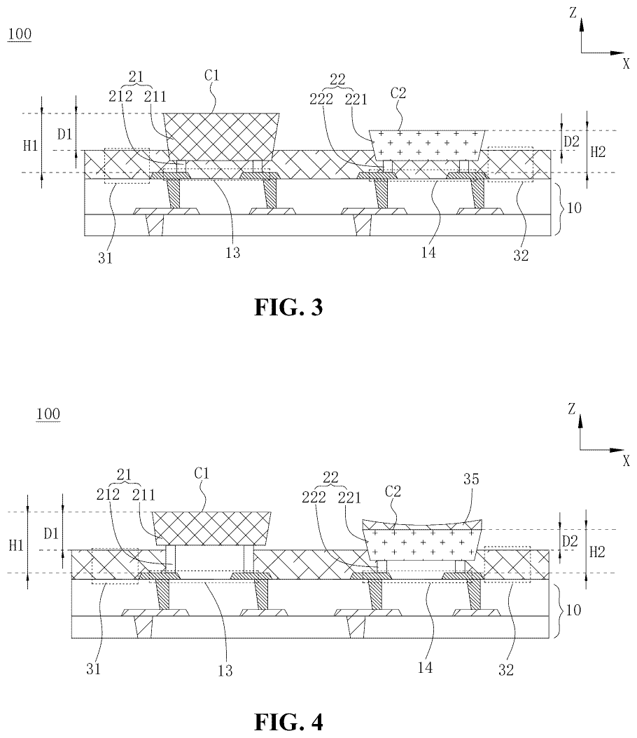

In some embodiments, referring to FIG. 3 and FIG. 4, the first light-emitting element 21 includes a first epitaxial structure 211 and a first electrode structure 212, and the second light-emitting element 22 includes a second epitaxial structure 221 and a second electrode structure 222. In the thickness direction Z of the array substrate 10, the size of the first epitaxial structure 211 is larger than the size of the second epitaxial structure 221; and/or, in the thickness direction Z of the array substrate 10, the size of the first electrode structure 212 is larger than the size of the second electrode structure 222.

The first electrode structure 212 and the first epitaxial structure 211 are important components of the first light-emitting element 21. The first epitaxial structure 211 may be used to emit light of a specific color, and the first electrode structure 212 is used to receive an electrical signal to drive the first epitaxial structure 211 to realize the light-emitting function. Herein, the first epitaxial structure 211 includes a plurality of film layer structures stacked, and the specific film layer composition mode in the first epitaxial structure 211 is not limited in the embodiments of the present application. Optionally, the first epitaxial structure 211 includes a first semiconductor layer, a light-emitting layer, and a second semiconductor layer that are stacked. Further, the first semiconductor layer includes, for example, an N-type semiconductor layer, the light-emitting layer includes, for example, a multiple quantum well structure, and the second semiconductor layer includes, for example, a P-type semiconductor layer, but is not limited thereto.

Considering that the first light-emitting element 21 can have a variety of structural forms, the first epitaxial structure 211 and the first electrode structure 212 can have a variety of positional relationships. Specifically, the types of the first light-emitting element 21 may include horizontal chips and vertical chips. According to different structures, the horizontal chips further include flip chips and wire-bonding chips. When the first light-emitting element 21 is a flip chip, the first epitaxial structure 211 may be located on one side of the first electrode facing away from the array substrate 10. When the first light-emitting element 21 is a wire-bonding chip, the first epitaxial structure 211 may be located on one side of the first electrode facing the array substrate 10. When the first light-emitting element 21 is a vertical chip, the two electrode portions of the first electrode are arranged on both sides of the first epitaxial structure 211 along a thickness direction Z of the array substrate 10 respectively. The second electrode structure 222 and the second epitaxial structure 221 in the second light-emitting element 22 are similar, which are not limited in the embodiments of the present application. Herein, the figure shows the situation when both the first light-emitting element 21 and the second light-emitting element 22 are flip chips.

On this basis, in order to meet the position requirements of the plane where the first light-emitting surface C1 is located and the plane where the second light-emitting surface C2 is located, the size of at least one of the first epitaxial structure 211 and the first electrode structure 212 is adjusted in the embodiments of the present application. Specifically, as shown in FIG. 3, a new film layer structure can be added inside the first epitaxial structure 211, or the thicknesses of the part of film layer structures existing in the first epitaxial structure 211 itself can be increased, so that in the thickness direction Z of the array substrate 10, the size of the first epitaxial structure 211 is larger than the size of the second epitaxial structure 221, so as to meet the need that the plane where the first light-emitting surface C1 is located is located on one side of the plane where the second light-emitting surface C2 is located facing away from the array substrate 10.

Alternatively, as shown in FIG. 4, the size of the first electrode structure 212 itself may be increased, and the size of the first electrode structure 212 in the thickness direction Z of the array substrate 10 may be set to be larger than the size of the second electrode structure 222, so as to increase the size of the first electrode structure 212 to increase the height of the plane where the first light-emitting surface C1 is located, thereby also satisfying the requirement that the plane where the first light-emitting surface C1 is located is located on one side of the plane where the second light-emitting surface C2 is located facing away from the array substrate 10.

In summary, in the embodiments of the present application, the size of at least one of the first epitaxial structure 211 and the first electrode structure 212 in the thickness direction Z of the array substrate 10 can be selectively increased, so that the plane where the first light-emitting surface C1 is located is located on one side of the plane where the second light-emitting surface C2 is located facing away from the array substrate 10, so that there is a large height difference between the first light-emitting surface C1 and the first light-shielding portion 31 without changing the array substrate 10, which has strong practicality and flexibility.

It should be noted that there may be a light-shielding material between the two electrodes of the first electrode structure 212, or there may not be a light-shielding material, which is not limited in the embodiments of the present application. Similarly, there may be a light-shielding material between the two electrodes in the second electrode structure 222, or there may not be a light-shielding material. Herein, FIG. 3 shows the case where there is a light-shielding material between the two electrodes of the first electrode structure 212, and FIG. 4 shows the case where there is no light-shielding material between the two electrodes of the first electrode structure 212.

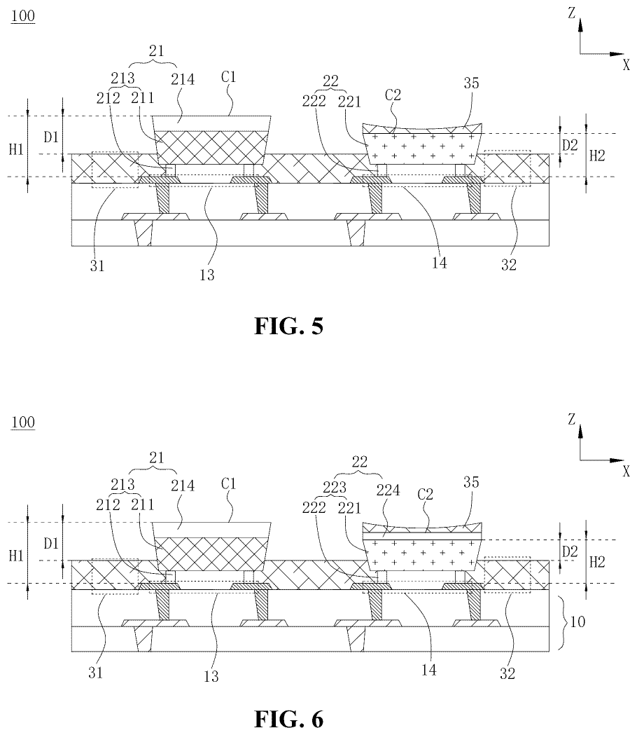

In some embodiments, referring to FIG. 5, the first light-emitting element 21 includes a first light-emitting body 213 and a first light-transmitting portion 214 located on one side of the first light-emitting body 213 facing away from the array substrate 10.

The first light-emitting body 213 is a core component of the first light-emitting element 21 for realizing the light-emitting function. Exemplarily, the first light-emitting body 213 may include a first epitaxial structure 211 and a first electrode structure 212. The first light-transmitting portion 214 is a film layer structure made of a light-transmitting material in the first light-emitting element 21 and located on a light-emitting side of the first light-emitting body 213. The first light-transmitting portion 214 can cover and protect the first light-emitting body 213, thereby reducing the risk of damage to the first light-emitting body 213. Herein, due to the existence of the first light-transmitting portion 214, the first light-emitting surface C1 is not a surface on the first epitaxial structure 211, but a surface located on one side of the first light-transmitting portion 214 facing away from the array substrate 10, and the first surface M1 is spaced apart from the first epitaxial structure 211.

The specific material, shape structure, etc. of the first light-transmitting portion 214 are not limited in the embodiments of the present application. Optionally, a roughness of a surface of the first light-transmitting portion 214 facing away from the array substrate 10, i.e., the first light-emitting surface C1, is less than that of a surface of the first epitaxial structure 211 facing away from the array substrate 10, i.e., the first light-emitting surface C1 on the first light-transmitting portion 214 is smoother than the surface of the first epitaxial structure 211, which is conducive to further increasing the probability of the light-shielding material on the first light-emitting surface C1 flowing to the periphery of the first light-emitting element 21, thereby improving the light extraction efficiency of the first light-emitting element 21.

Further optionally, a refractive index of the first light-transmitting portion 214 is less than a refractive index of the first epitaxial structure 211, which can reduce the probability of total reflection of light at an interface between the first light-transmitting portion 214 and the first light-emitting body 213, thereby improving the light extraction efficiency.

In addition, the preparation method of the first light-transmitting portion 214 is not limited in the embodiments of the present application. Exemplarily, the first light-transmitting portion 214 may be prepared and formed together with the first light-emitting body 213. Alternatively, the first light-emitting body 213 may be first transferred to the array substrate 10, the first light-transmitting portion 214 may be prepared on the first light-emitting body 213, and then the light-shielding layer 30 may be formed. Alternatively, it may be prepared during transportation, such as retaining the transfer glue.

In the embodiments of the present application, in addition to protecting the first light-emitting body 213, the first light-transmitting portion 214 may also adjust the light-emitting effect of the first light-emitting element 21 by adjusting the material composition of the first light-transmitting portion 214, which has strong practicality. Furthermore, the existence of the first light-transmitting portion 214 may also increase the height of the first light-emitting surface C1, thereby increasing the height difference between the first light-emitting surface C1 and the first light-shielding portion 31, increasing the probability that the light-shielding material at the first light-emitting surface C1 flows to the periphery of the first light-emitting element 21, improving the light extraction efficiency of the first light-emitting element 21, and reducing the brightness difference between the first light-emitting element 21 and the second light-emitting element 22, which is conducive to improving display uniformity and display effect.

It should be noted that, for the second light-emitting element 22, the second light-emitting element 22 may be provided with a light-transmitting portion or may not be provided with a light-transmitting portion, which is not limited in the embodiments of the present application.

In some embodiments, referring to FIG. 6, the second light-emitting element 22 includes a second light-emitting body 223 and a second light-transmitting portion 224 located on one side of the second light-emitting body 223 facing away from the array substrate 10, where a size of the first light-transmitting portion 214 is larger than a size of the second light-transmitting portion 224 in the thickness direction Z of the array substrate 10.

For a relationship between the second light-transmitting portion 224 and the second light-emitting body 223, as well as the function and material composition of the second light-transmitting portion 224, referring to the description of the first light-transmitting portion 214 and the first light-emitting body 213 in the aforementioned embodiments, which are not repeated in the embodiments of the present application.

In the embodiments of the present application, in view of the situation that the first light-emitting element 21 includes the first light-transmitting portion 214 and the second light-emitting element 22 includes the second light-transmitting portion 224, the sizes of the first light-transmitting portion 214 and the second light-transmitting portion 224 are designed differently, so that the plane where the first light-emitting surface C1 is located is located on one side of the plane where the second light-emitting surface C2 is located facing away from the array substrate 10 without changing the first light-emitting body 213 and the second light-emitting body 223. Under a premise of increasing the height difference between the first light-emitting surface C1 and the first light-shielding portion 31, the difficulty of preparing and designing the first light-emitting body 213 and the second light-emitting body 223 is reduced, which is conducive to improving the preparation yield of the first light-emitting element 21 and the second light-emitting element 22.

In some embodiments, as shown in FIG. 3 to FIG. 6, the size of the first light-emitting element 21 in the thickness direction Z of the array substrate 10 is H1, and the size of the second light-emitting element 22 in the thickness direction Z of the array substrate 10 is H2, where H1 and H2 satisfy: 1.05≤H1/H2≤1.5. Optionally, H1/H2 is equal to one of 1.05, 1.1, 1.2, 1.3, 1.4 and 1.5.

In the embodiments of the present application, by setting the size H1 of the first light-emitting element 21 to be larger than the size H2 of the second light-emitting element 22, the plane where the first light-emitting surface C1 is located is located on one side of the plane where the second light-emitting surface C2 is located facing away from the array substrate 10. On this basis, H1/H2 is also set to not less than 1.05 in the embodiments of the present application, which is conducive to increasing the height difference between the first light-emitting surface C1 and the first light-shielding portion 31, thereby reducing the residual light-shielding material at the first light-emitting surface C1 and improving the light extraction efficiency corresponding to the first light-emitting element 21. At the same time, H1/H2 is set to not more than 1.5, thereby reducing the adverse effect on the overall thickness of the display panel 100 caused by the excessive size H1 of the first light-emitting element 21, which is conducive to achieving a lightweight design.

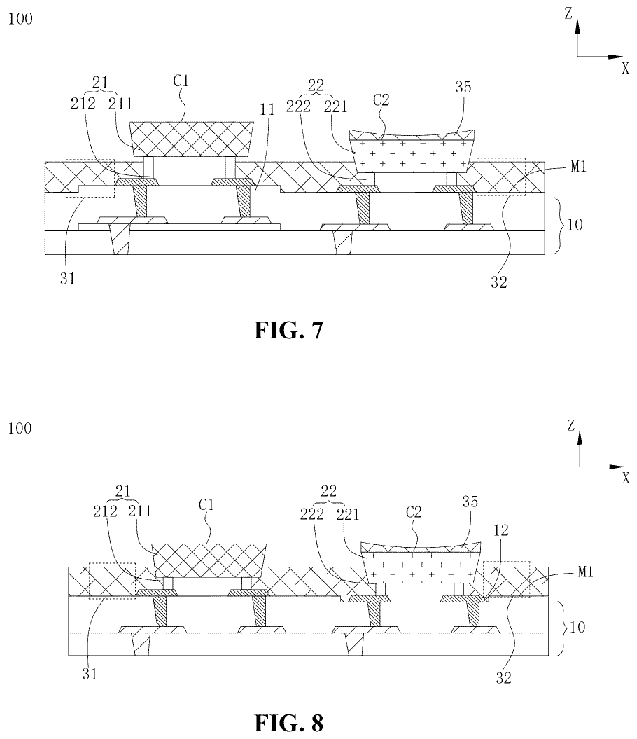

In some embodiments, referring to FIG. 7 and FIG. 8, the array substrate 10 has a first surface M1 and a convex portion 11 protruding from the first surface M1, the light-emitting element 20 is located on one side of the first surface M1, and along the thickness direction Z of the array substrate 10, the first light-emitting element 21 overlaps the convex portion 11. And/or, the array substrate 10 has a first surface M1 and a concave portion 12 that is concave inwardly relative to the first surface M1, the light-emitting element 20 is located on one side of the first surface M1, and along the thickness direction Z of the array substrate 10, the second light-emitting element 22 overlaps the concave portion 12.

The first surface M1 is a surface of the array substrate 10 in its own thickness direction Z, the first light-emitting element 21 and the second light-emitting element 22 are both located on one side of the first surface M1, and the light-shielding layer 30 is also located on one side of the first surface M1 and can be arranged in affixed with the first surface M1. On this basis, the height difference between the plane where the first light-emitting surface C1 is located and the first surface M1 is generally negatively correlated with the size of the light-shielding material remaining on the first light-emitting element 21. Similarly, the height difference between the plane where the second light-emitting surface C2 is located and the first surface M1 is generally negatively correlated with the size of the light-shielding material remaining on the second light-emitting element 22.

In view of this, as shown in FIG. 7, a convex portion 11 protruding from the first surface M1 and corresponding to the first light-emitting element 21 may be formed by increasing the thickness of a specific film layer such as an insulating layer or a conductor layer, or adding a new film layer structure such as an insulating layer or a conductor layer in the array substrate 10 in the embodiments of the present application. The existence of the convex portion 11 can increase the height of the first light-emitting element 21, so that the plane where the first light-emitting surface C1 is located is located on one side of the plane where the second light-emitting surface C2 is located facing away from the array substrate 10, a height difference between the plane where the first light-emitting surface C1 is located and the first surface M1 can be controlled to be greater than a height difference between the plane where the second light-emitting surface C2 is located and the first surface M1, and the light-shielding material remaining on the first light-emitting surface C1 is more likely to flow to the first surface M1, thereby improving the light extraction efficiency corresponding to the first light-emitting element 21, reducing the brightness difference between the first light-emitting element 21 and the second light-emitting element 22, which is conducive to improving display uniformity and display effect.

Alternatively, as shown in FIG. 8, in the embodiments of the present application, a part of structure of a film layer such as a specific insulating layer or conductor layer in the array substrate 10 at the second light-emitting element 22 can be removed to form a concave portion 12 that is concave inwardly with respect to the first surface M1 and corresponds to the second light-emitting element 22. The presence of the concave portion 12 can cause the second light-emitting element 22 to sink with respect to the first light-emitting element 21. With this design, the height difference between the plane where the first light-emitting surface C1 is located and the first surface M1 can also be controlled to be greater than the height difference between the plane where the second light-emitting surface C2 is located and the first surface M1, which is conducive to reducing the brightness difference between the first light-emitting element 21 and the second light-emitting element 22, and improving display uniformity and display effect.

It should be noted that, according to different actual needs, the array substrate 10 may only have a convex portion 11 that is protruding with respect to the first surface M1, or may only have a concave portion 12 that is concave inwardly with respect to the first surface M1, or may have both a concave portion 12 and a convex portion 11, which is not limited in the embodiments of the present application.

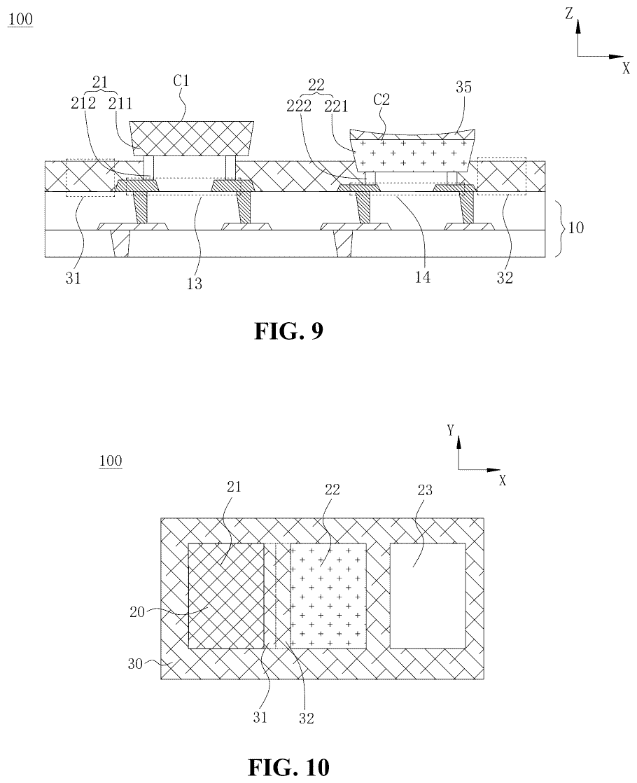

In some embodiments, referring to FIG. 9, the array substrate 10 includes a bonding pad structure and a pixel circuit, the bonding pad structure is electrically connected to the light-emitting element 20 and the pixel circuit each, and a plurality of bonding pad structures include a first bonding pad 13 electrically connected to the first light-emitting element 21, and a second bonding pad 14 electrically connected to the second light-emitting element 22, along the thickness direction Z of the array substrate 10, the first bonding pad 13 overlaps the first light-emitting element 21, the second bonding pad 14 overlaps the second light-emitting element 22, and a size of the first bonding pad 13 is larger than a size of the second bonding pad 14.

The pixel circuit is a circuit structure for driving and controlling whether the light-emitting element 20 emits light or not, and the pixel circuit may include a storage capacitor and a plurality of thin film transistors, where the pixel circuit may have a variety of forms, which is not limited in the embodiments of the present application. Optionally, the pixel circuit may be in a 7T1C structure, that is, a single pixel circuit includes seven thin film transistors and a storage capacitor, or the pixel circuit may also be in an 8T1C structure.

The bonding pad structure is a structure arranged on the first surface M1 and used to be welded and fixed to the electrode structure on the light-emitting element 20. The first bonding pad 13 structure is electrically connected to the first light-emitting element 21. The first bonding pad 13 structure may include two bonding pads spaced apart and insulated. The two bonding pads are connected and fixed to the two electrodes in the first electrode structure 212 respectively and used to realize the electrical connection between the first light-emitting element 21 and the corresponding pixel circuit. The second bonding pad 14 structure is electrically connected to the second light-emitting element 22. The composition of the second bonding pad 14 structure is similar to that of the first bonding pad 13 structure, which is not repeated in the embodiments of the present application.

Furthermore, in the embodiments of the present application, the size of the first bonding pad 13 structure is adjusted so that in the thickness direction Z of the array substrate 10, the size of the first bonding pad 13 structure is larger than the size of the second bonding pad 14 structure. In this way, the first light-emitting element 21 is raised by means of the first bonding pad 13 structure, so that the plane where the first light-emitting surface C1 is located is located on one side of the plane where the second light-emitting surface C2 is located facing away from the array substrate 10, during the preparation process of the light-shielding layer 30, it is conducive to realizing the downward flow of the light-shielding material on the first light-emitting surface C1, thereby improving the light extraction efficiency of the first light-emitting element 21, reducing the brightness difference between the first light-emitting element 21 and the second light-emitting element 22, and improving the display uniformity and display effect.

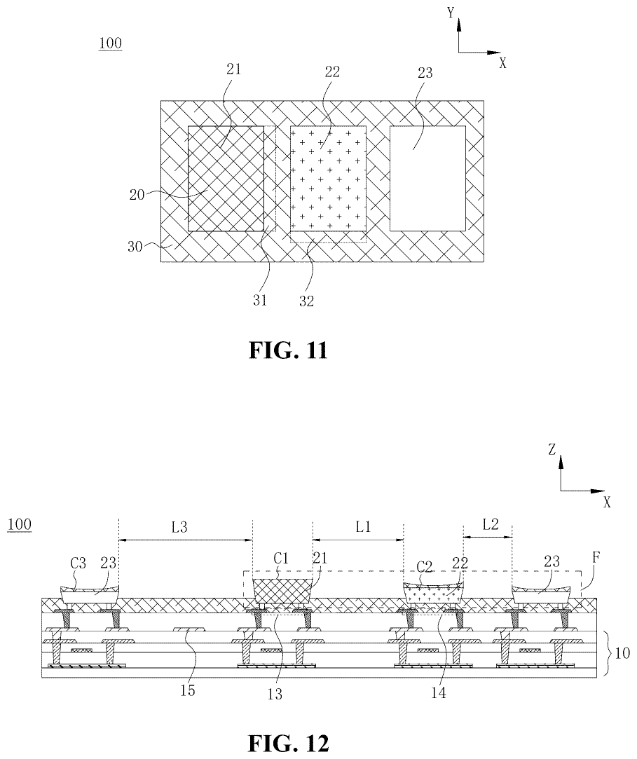

In some embodiments, referring to FIG. 1, FIG. 2, FIG. 10 and FIG. 11, the first light-emitting element 21 and the second light-emitting element 22 are arranged adjacent to each other, and the first light-shielding portion 31 and the second light-shielding portion 32 are both located between the first light-emitting element 21 and the second light-emitting element 22 adjacent to each other; or, the first light-shielding portion 31 is located on one side of the first light-emitting element 21 facing away from the second light-emitting element 22; or, the second light-shielding portion 32 is located on one side of the second light-emitting element 22 facing away from the first light-emitting element 21; or, the first light-shielding portion 31 is located on one side of the first light-emitting element 21 along the first direction X, and the second light-shielding portion 32 is located on one side of the second light-emitting element 22 along the second direction Y, and the first direction X and the second direction Y are both parallel to the plane where the array substrate 10 is located and intersect each other.

The first light-emitting element 21 and the second light-emitting element 22 may be two light-emitting elements 20 arranged adjacent to each other, and on this basis, the first light-shielding portion 31 and the second light-shielding portion 32 can have a variety of positional relationships. Specifically, as shown in FIG. 10, the first light-shielding portion 31 and the second light-shielding portion 32 can both be located between the first light-emitting element 21 and the second light-emitting element 22. In this case, the first light-shielding portion 31 and the second light-shielding portion 32 can be connected and integrated, and a surface of one side of the first light-shielding portion 31 facing away from the array substrate 10 and a surface of one side of the second light-shielding portion 32 facing away from the array substrate 10 may be located on the same surface. On this basis, in order to enable the height difference between the first light-emitting surface C1 and the first light-shielding portion 31 to be greater than the height difference between the second light-emitting surface C2 and the second light-shielding portion 32, it is necessary to dispose the plane where the first light-emitting surface C1 is located to be located on one side of the plane where the second light-emitting surface C2 is located facing away from the array substrate 10.

Alternatively, as shown in FIG. 1, the first light-shielding portion 31 may also be located on one side of the first light-emitting element 21 facing away from the second light-emitting element 22. In this case, no matter the second light-shielding portion 32 is located between the first light-emitting element 21 and the second light-emitting element 22, or located on one side of the second light-emitting element 22 facing away from the first light-emitting element 21, the second light-shielding portion 32 is spaced apart from the first light-shielding portion 31. On this basis, in order to enable the height difference between the first light-emitting surface C1 and the first light-shielding portion 31 to be greater than the height difference between the second light-emitting surface C2 and the second light-shielding portion 32, in addition to disposing the plane where the first light-emitting surface C1 is located to be located on one side of the plane where the second light-emitting surface C2 is located facing away from the array substrate 10, the structure of the array substrate 10 at the first light-shielding portion 31 may also be concave inwardly, so that the upper surface of the first light-shielding portion 31 is located on one side of the upper surface of the second light-shielding portion 32 close to the array substrate 10.

Alternatively, as shown in FIG. 1, the second light-shielding portion 32 may also be located on one side of the second light-emitting element 22 facing away from the first light-emitting element 21. This situation is similar to the above-mentioned content and is not repeated in the embodiments of the present application.

Alternatively, as shown in FIG. 11, the first light-shielding portion 31 may also be located on one side of the first light-emitting element 21 along the first direction X, and the second light-shielding portion 32 may be located on one side of the second light-emitting element 22 along the second direction Y. In other words, the first light-shielding portion 31 and the second light-shielding portion 32 are arranged on one side of the first light-emitting element 21 and the second light-emitting element 22 along different directions respectively. At this time, the first light-shielding portion 31 and the second light-shielding portion 32 are also spaced apart from each other, and in addition to adjusting the plane where the first light-emitting surface C1 is located, the first light-shielding portion 31 can also be adjusted to meet the requirement that the height difference between the first light-emitting surface C1 and the first light-shielding portion 31 is greater than the height difference between the second light-emitting surface C2 and the second light-shielding portion 32.

In some embodiments, as shown in FIG. 1 and FIG. 2, a plurality of light-emitting elements 20 also include a third light-emitting element 23 having a color different from those of the first light-emitting element 21 and the second light-emitting element 22, and the third light-emitting element 23 has a third light-emitting surface C3 facing away from the array substrate 10. The light-shielding portion includes a third light-shielding portion 33 adjacent to the third light-emitting element 23, and in the thickness direction Z of the array substrate 10, a distance between the plane where the first light-emitting surface C1 is located and the first light-shielding portion 31 is greater than a distance between the third light-emitting surface C3 and the third light-shielding portion 33.

The third light-emitting element 23 is a light-emitting element 20 having a light-emitting color different from those of the first light-emitting element 21 and the second light-emitting element 22. Positional relationships of the third light-emitting element 23 with respect to the first light-emitting element 21 and the second light-emitting element 22 are not limited in the embodiments of the present application. Optionally, the first light-emitting element 21, the second light-emitting element 22 and the third light-emitting element 23 may be arranged in the same direction, or an arrangement direction between the first light-emitting element 21 and the third light-emitting element 23 may also be different from an arrangement direction between the first light-emitting element 21 and the second light-emitting element 22.

The third light-emitting element 23 has a third light-emitting surface C3, the third light-emitting surface C3 is a light-emitting surface on the third light-emitting element 23. The light-shielding layer 30 includes a third light-shielding portion 33, the third light-shielding portion 33 is a part of structure of the light-shielding layer 30 located on the periphery of the third light-emitting element 23 and in contact with the side surface of the third light-emitting element 23. A relative positional relationship between the third light-emitting element 23 and the third light-shielding portion 33, and positional relationships of the third light-shielding portion 33 with respect to the first light-shielding portion 31 and the second light-shielding portion 32 are not limited in the embodiments of the present application.

In the embodiments of the present application, the height difference between the plane where the first light-emitting surface C1 is located and the first light-shielding portion 31 is set to be greater than the height difference between the third light-emitting surface C3 and the third light-shielding portion 33, so that the light-shielding material remaining on the first light-emitting surface C1 is more likely to flow downward to the peripheral side of the first light-emitting element 21, thereby improving the light extraction efficiency corresponding to the first light-emitting element 21, reducing the brightness difference between the first light-emitting element 21 and the third light-emitting element 23, which are conducive to improving display uniformity and display effect.

It should be noted that if there is a difference in light extraction efficiency between the second light-emitting element 22 and the third light-emitting element 23, in the thickness direction Z of the array substrate 10, it is also possible to choose to set a distance between the plane where the second light-emitting surface C2 is located and the second light-shielding portion 32 to be different from a distance between the third light-emitting surface C3 and the third light-shielding portion 33, so as to reduce the difference in light extraction efficiency between the second light-emitting element 22 and the third light-emitting element 23 and improve display uniformity. Herein, the specific setting method can refer to the setting method adopted in the aforementioned embodiments, and the embodiments of the present application may not be repeated.

In some embodiments, referring to FIG. 12 to FIG. 14, a plurality of light-emitting elements 20 form a repeating unit F, and a plurality of repeating units F are arranged repeatedly, and the repeating unit F includes a first light-emitting element 21, a second light-emitting element 22, and a third light-emitting element 23 arranged adjacently one another in sequence, where a distance L1 between the first light-emitting element 21 and the second light-emitting element 22 adjacent to each other is greater than a distance L2 between the second light-emitting element 22 and the third light-emitting element 23 adjacent to each other.

The display panel 100 includes a plurality of repeating units F, and the types and arrangement relationships of the light-emitting elements 20 in each repeating unit F are consistent, where a plurality of repeating units F may be arranged only in a single direction, or a plurality of repeating units F may also be arranged in multiple directions, which is not limited in the embodiments of the present application. Optionally, a plurality of repeating units F are arranged in a first direction X and a second direction Y, respectively.

The repeating unit F includes a first light-emitting element 21, a second light-emitting element 22, and a third light-emitting element 23 arranged adjacently one another in sequence, and the first light-emitting element 21, the second light-emitting element 22, and the third light-emitting element 23 are different light-emitting elements 20 used to form the same repeating unit F, where the luminous colors of any two of the first light-emitting element 21, the second light-emitting element 22 and the third light-emitting element 23 are the same, or may be different. Optionally, the luminous colors corresponding to the first light-emitting element 21, the second light-emitting element 22 and the third light-emitting element 23 are all different.

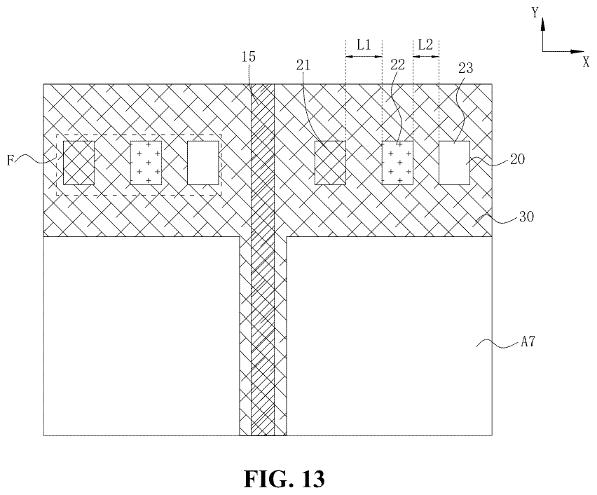

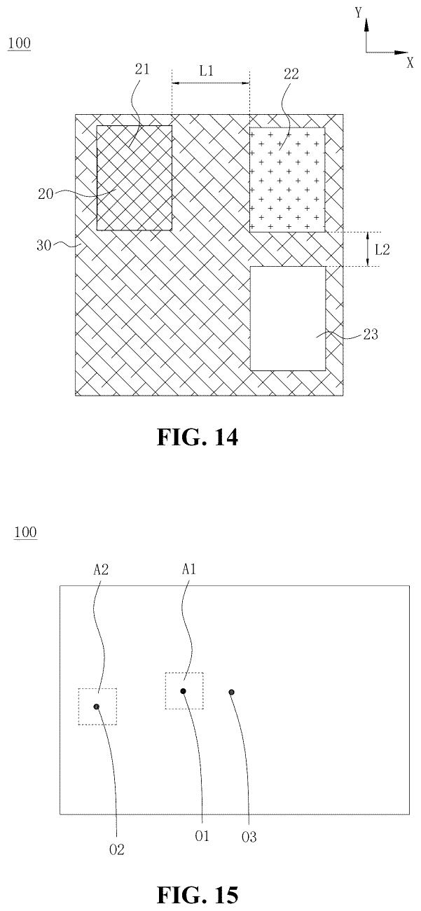

It should be noted that the specific arrangement of the first light-emitting element 21, the second light-emitting element 22 and the third light-emitting element 23 in a single repeating unit F is not limited in the embodiments of the present application. Exemplarily, as shown in FIG. 12 and FIG. 13, the first light-emitting element 21, the second light-emitting element 22 and the third light-emitting element 23 may be arranged adjacently one another in sequence along the first direction X, or referring to FIG. 14, the first light-emitting element 21 and the second light-emitting element 22 are arranged adjacent to each other along the first direction X, and the second light-emitting element 22 and the third light-emitting element 23 are arranged adjacent to each other along the second direction Y. Herein, FIG. 13 shows a situation when the display panel is a transparent display panel. Specifically, the display panel may include a transparent area A7, and there is no light-shielding material and light-emitting element structure at the transparent area A7, so as to achieve a transparent display function by means of the transparent area A7. Further, a first signal line 15 and a light-shielding material for shielding the first signal line 15 may exist outside the transparent area A7 and in the area between adjacent repeating units F.

In addition, a single repeating unit F may include only the first light-emitting element 21, the second light-emitting element 22 and the third light-emitting element 23, or may also include other light-emitting elements 20, which is not limited in the embodiments of the present application. As long as the first light-emitting element 21, the second light-emitting element 22 and the third light-emitting element 23 can be included in a single repeating unit F at the same time, and the first light-emitting element 21 is adjacent to the second light-emitting element 22, and the second light-emitting element 22 is adjacent to the third light-emitting element 23.

Further, the distance L1 between the first light-emitting element 21 and the second light-emitting element 22 adjacent to each other is set to be greater than the distance L2 between the second light-emitting element 22 and the third light-emitting element 23 adjacent to each other in the embodiments of the present application. Herein, the “distance between first light-emitting elements 21 and second light-emitting elements 22 adjacent to each other” mentioned here refers to: in a single repeating unit F, an average distance between an edge of the first light-emitting element 21 facing the second light-emitting element 22 and an edge of the second light-emitting element 22 facing the first light-emitting element 21. Considering the differences in the shapes and layout modes of the first light-emitting element 21 and the second light-emitting element 22, the edge of the first light-emitting element 21 mentioned here may be a straight line, or a broken line or a curve, etc. The edge of the second light-emitting element 22 is the same. That is, the first light-emitting element 21 may be arranged directly opposite to the second light-emitting element 22 in an arrangement direction, or may be arranged not directly opposite to the second light-emitting element 22 in the arrangement direction. The distance between the second light-emitting element 22 and the third light-emitting element 23 adjacent to each other is the same, which is not repeated in the embodiments of this application.

In the embodiments of the present application, by setting the distance L1 between the first light-emitting element 21 and the second light-emitting element 22 adjacent to each other to be greater than the distance L2 between the second light-emitting element 22 and the third light-emitting element 23 adjacent to each other, a larger space can be provided between the first light-emitting element 21 and the second light-emitting element 22 for accommodating the light-shielding material. On this basis, it is more likely that the light-shielding material located on the first light-emitting element 21 can flow between the first light-emitting element 21 and the second light-emitting element 22, thereby improving the light extraction efficiency corresponding to the first light-emitting element 21, reducing the brightness differences of the first light-emitting element 21 and other light-emitting elements 20, which is conducive to improving the display uniformity and display effect.

It should be noted that in order to improve the light extraction efficiency corresponding to the first light-emitting element 21, only the height difference between the first light-emitting surface C1 and the first light-shielding portion 31 may be set to be greater than the height differences of other light-emitting surfaces and the corresponding light-shielding portion. Alternatively, only the distance L1 between the first light-emitting element 21 and the second light-emitting element 22 adjacent to each other may be set to be greater than the distance L2 between the second light-emitting element 22 and the third light-emitting element 23 adjacent to each other. Alternatively, the height difference between the first light-emitting surface C1 and the first light-shielding portion 31 may be set to be greater than the height differences of other light-emitting surfaces and the corresponding light-shielding portion, and the distance L1 between the first light-emitting element 21 and the second light-emitting element 22 adjacent to each other may be set to be greater than the distance L2 between the second light-emitting element 22 and the third light-emitting element 23 adjacent to each other. In other words, the light extraction efficiency corresponding to the first light-emitting element 21 may be improved in a variety of ways, which is not overly limited in the embodiments of the present application.

In some embodiments, as shown in FIG. 12, the first light-emitting element 21 in one repeating unit F is disposed adjacent to the third light-emitting element 23 in the other repeating unit F. Herein, the distance L3 between the first light-emitting element 21 and the third light-emitting element 23 adjacent to each other is greater than the distance L2 between the second light-emitting element 22 and the third light-emitting element 23 adjacent to each other.

Compared with the distance between adjacent light-emitting elements 20 in a single repeating unit F, a distance between adjacent two of the light-emitting elements 20 in adjacent two of the repeating units F is generally larger. On this basis, a position of the first light-emitting element 21 in the repeating unit F is adjusted in the embodiments of the present application, so that the first light-emitting element 21 is located at the edge position of the repeating unit F with respect to the other light-emitting elements 20, in adjacent two of the repeating units F, the first light-emitting element 21 in one repeating unit F can be disposed adjacent to the third light-emitting element 23 in the other repeating unit F.

Under this design, the distance L3 between the first light-emitting element 21 and the third light-emitting element 23 adjacent to each other can be greater than the distance L2 between the second light-emitting element 22 and the third light-emitting element 23 adjacent to each other, so that there is a larger space between the first light-emitting element 21 and the third light-emitting element 23 for accommodating the light-shielding material. On this basis, it is more likely that the light-shielding material located on the first light-emitting element 21 can flow between the first light-emitting element 21 and the third light-emitting element 23, thereby improving the light extraction efficiency corresponding to the first light-emitting element 21, reducing the brightness differences of the first light-emitting element 21 and other light-emitting elements 20, which is conducive to improving display uniformity and display effect.

In some embodiments, as shown in FIG. 12 and FIG. 13, the array substrate 10 includes a first signal line 15, along the thickness direction Z of the array substrate 10, the first signal line 15 does not overlap the repeating unit F, and along the arrangement direction of the repeating unit F, the first signal line 15 is located between adjacent repeating units F.

The first signal is a metal routing line used for transmitting a specific signal. Exemplarily, the first signal line 15 can be used to transmit one of the scanning signal scan, the data signal Lata, the power signal pvLL, the power signal pvee, and the reset signal vref. The first signal line 15 is at least partially located between adjacent repeating units F. On this basis, the shielding portion located between adjacent light-emitting elements 20 can cover and shield the first signal line 15, reduce the reflection effect of the first signal line 15 on light, and improve the display effect of the display panel 100.

On this basis, in order to meet the need to avoid the first signal line 15, there may be a large distance between adjacent repeating units F. Further, by adjusting the first light-emitting element 21 to the edge position in the repeating unit F, there may be a large distance between the first light-emitting element 21 and the third light-emitting element 23 adjacent to each other, which is conducive to further improving the light extraction efficiency corresponding to the first light-emitting element 21, reducing the brightness differences of the first light-emitting element 21 and other light-emitting elements 20, and improving display uniformity and display effect.

In some embodiments, in adjacent repeating units F, the distance L3 between first light-emitting elements 21 and third light-emitting elements 23 adjacent to each other is greater than the distance L1 between first light-emitting elements 21 and second light-emitting elements 22 adjacent to each other.

In combination with the foregoing, it can be seen that the distance between first light-emitting elements 21 and third light-emitting elements 23 adjacent to each other can be relatively large to meet the need to avoid the first signal line 15. On this basis, the distance L3 between the first light-emitting element 21 and the third light-emitting element 23 adjacent to each other may also be greater than the distance L1 between the first light-emitting element 21 and the second light-emitting element 22 adjacent to each other, that is, the space size between the first light-emitting element 21 and the third light-emitting element 23 adjacent to each other is greater than the space size between the first light-emitting element 21 and the second light-emitting element 22 adjacent to each other. In this way, by means of the space between the first light-emitting element 21 and the third light-emitting element 23 adjacent to each other, more light-shielding materials located on the first light-emitting surface C1 can flow between the first light-emitting element 21 and the third light-emitting element 23, thereby further reducing the shielding of the first light-emitting element 21 by the light-shielding material, improving the light extraction efficiency corresponding to the first light-emitting element 21, reducing the brightness differences of the first light-emitting element 21 and other light-emitting elements 20, which is conducive to improving display uniformity and display effect.

In some embodiments, the distance between the first light-emitting element 21 and the second light-emitting element 22 adjacent to each other is L1, and the distance between the second light-emitting element 22 and the third light-emitting element 23 adjacent to each other is L2, where L1 and L2 satisfy: 1.2≤L1/L2≤100. Optionally, L1/L2 is equal to one of 1.2, 2, 10, 50, 80 and 100.

In the embodiments of the present application, by setting the distance L1 between the first light-emitting element 21 and the second light-emitting element 22 adjacent to each other to be greater than the distance L2 between the second light-emitting element 22 and the third light-emitting element 23 adjacent to each other, it is more likely that the light-shielding material located on the first light-emitting element 21 can flow between the first light-emitting element 21 and the second light-emitting element 22. On this basis, L1/L2 is set to not less than 1.2 in the embodiments of the present application, which is conducive to ensuring that there is a certain space size between the first light-emitting element 21 and the second light-emitting element 22 adjacent to each other to meet the flow requirements of the light-shielding material on the first light-emitting element 21 and improve the light extraction efficiency corresponding to the first light-emitting element 21. At the same time, L1/L2 is also set to not more than 100, thereby reducing the problem of insufficient overall resolution of the display panel 100 due to the excessive distance L1 between the first light-emitting element 21 and the second light-emitting element 22 adjacent to each other, which is conducive to improving the display effect of the display panel 100.

In some embodiments, referring to FIG. 12 and FIG. 15, the display panel 100 has a first area A1 and a second area A2, and the distance between the center O1 of first area A1 and the center O3 of display panel 100 is smaller than the distance between the center O2 of second area A2 and the center O3 of display panel 100. A distance between the first light-emitting element 21 and the second light-emitting element 22 adjacent to each other in the first area A1 is greater than a distance between the first light-emitting element 21 and the second light-emitting element 22 in the second area A2.

The first area A1 and the second area A2 are two different areas on the display panel 100, where the first area A1 and the second area A2 both have a variety of shapes, for example, the first area A1 and the second area A2 may both be in regular or irregular shapes such as round or square, or the shapes corresponding to the first area A1 and the second area A2 may also be different, which is not limited in the present embodiments of the application.

The distance between the center O1 of first area A1 and the center O3 of display panel 100 is smaller than the distance between the center O2 of second area A2 and the center O3 of display panel 100. Specifically, a length of the line between the center O1 of first area A1 and the center O3 of display panel 100 is less than a length of the line between the center O2 of second area A2 and the center O3 of display panel 100. The first area A1 may include the display panel 100, or the first area A1 may not include the center O3 of display panel 100. Further, the center O1 of first area A1 may coincide with the center O3 of display panel 100, or the center O1 of first area A1 may not coincide with the center O3 of display panel 100.

It should be noted that due to the influence of factors such as the shape of the display panel 100 itself and the difference in local structure, the “center O3 of display panel 100” mentioned here is not necessarily completely at the center of the display panel 100, and there may be a certain deviation, and the same applies to the center O1 of first area A1 and the center O2 of second area A2.

During the use of the display panel 100, since the first area A1 is closer to the center O3 of display panel 100 than the second area A2, and the second area A2 is closer to the edge of the display panel 100 than the first area A1, the heat generated in the second area A2 can be heat exchanged with the side environment of the display panel 100, resulting in that in the related art, the temperature of the display panel 100 in the second area A2 is generally lower than the temperature in the first area A1.

In view of this, the light-emitting elements 20 in the first area A1 and the second area A2 are designed differently in the embodiments of the present application, by setting the distance between the first light-emitting element 21 and the second light-emitting element 22 adjacent to each other in the first area A1 to be greater than the distance between the first light-emitting element 21 and the second light-emitting element 22 in the second area A2, thereby reducing the heat accumulation in the first area A1 by means of this design, so as to balance the temperature difference between the first area A1 and the second area A2, and improve the usage reliability of the display panel 100.

In addition, since there is a large distance between the first light-emitting element 21 and the second light-emitting element 22 adjacent to each other in the first area A1, it is more likely that the light-shielding material in the first area A1 and located on the first light-emitting element 21 flow between the first light-emitting element 21 and the second light-emitting element 22 through this design, so as to improve the light extraction efficiency of the first light-emitting element 21 in the first area A1.

In some embodiments, as shown in FIG. 4 to FIG. 8, the light-shielding layer 30 includes a second light-shielding material portion 35 located on one side of the second light-emitting element 22 facing away from the array substrate 10.

The second light-shielding material portion 35 is a light-shielding material remaining on the second light-emitting surface C2. The presence of the second light-shielding material portion 35 may have an adverse effect on the light extraction efficiency of the second light-emitting element 22. However, compared with the first light-emitting element 21, due to factors such as the brightness and color sensitivity of the second light-emitting element 22 itself, the second light-shielding material portion 35 has a smaller effect on the light extraction efficiency of the second light-emitting element 22. Therefore, the display panel 100 can achieve a good display effect under the premise of the presence of the second light-shielding material portion 35.

It should be noted that, by adjusting the structure of the first light-emitting element 21 itself or other structures at the periphery of the first light-emitting element 21, the light-shielding material may exist on the first light-emitting surface C1 of the first light-emitting element 21, or there may be no light-shielding material existed on the first light-emitting surface C1 of the first light-emitting element 21, which is not limited in the embodiments of the present application.

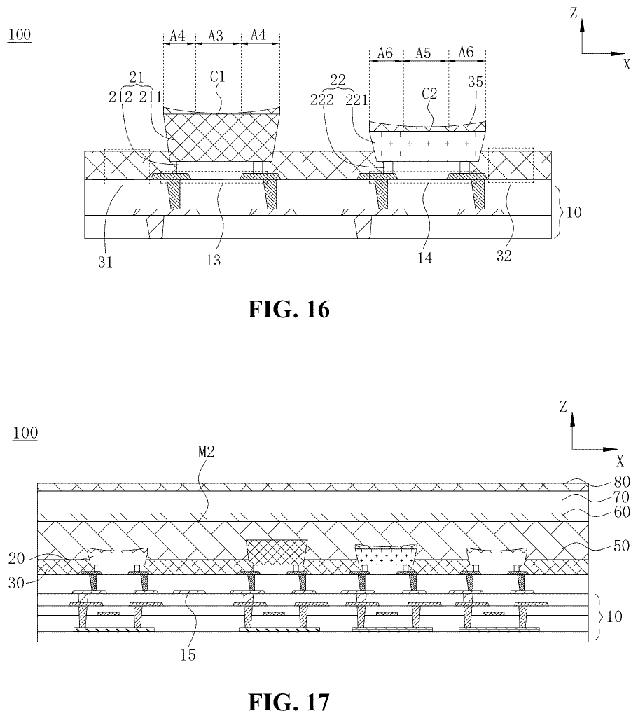

In some embodiments, referring to FIG. 16, the light-shielding layer 30 includes a first light-shielding material portion 34 located on one side of the first light-emitting element 21 facing away from the array substrate 10, and in the thickness direction Z of the array substrate 10, a size of the first light-shielding material portion 34 is smaller than a size of the second light-shielding material portion 35. The “size of the first light-shielding material portion 34” mentioned here refers to an average size of the first light-shielding material portion 34 in the thickness direction Z of the array substrate 10. Similarly, the “size of the second light-shielding material portion 35” refers to an average size of the second light-shielding material portion 35 in the thickness direction Z of the array substrate 10.

In the embodiments of the present application, the first light-shielding material portion 34 is a light-shielding material remaining on the first light-emitting surface C1. Since the height difference between the first light-emitting surface C1 and the first light-shielding portion 31 is set to be greater than the height differences of other light-emitting surfaces and the corresponding light-shielding portion, or the distance between the first light-emitting element 21 and the second light-emitting element 22 adjacent to each other is set to be greater than the distance between the second light-emitting element 22 and the third light-emitting element 23 adjacent to each other, more light-shielding material located on the first light-emitting surface C1 can flow to the periphery of the first light-emitting element 21, thereby making the size of the first light-shielding material portion 34 smaller than the size of the second light-shielding material portion 35, that is, with respect to the second light-emitting element 22, the first light-emitting element 21 is less affected by the light shielding, thereby reducing the brightness difference between the first light-emitting element 21 and the second light-emitting element 22, which is conducive to improving the display uniformity and display effect.

In some embodiments, the first light-emitting surface C1 has a first central area A3 and a first edge area A4 located on the periphery of the first central area A3. In the thickness direction Z of the array substrate 10, a size of the first light-shielding material portion 34 in the first central area A3 is smaller than a size of the first light-shielding material portion 34 in the first edge area A4. The second light-emitting surface C2 has a second central area A5 and a second edge area A6 located on a periphery of the second central area A5. In the thickness direction Z of the array substrate 10, a size of the second light-shielding material portion 35 in the second central area A5 is smaller than a size of the second light-shielding material portion 35 in the second edge area A6.

The first central area A3 is a central area of the first light-emitting surface C1, and the first edge area A4 is an edge area of the first light-emitting surface C1. Herein, sizes and shapes of the first central area A3 and the first edge area A4 are not limited in the embodiments of the present application. Optionally, a shape of the first central area A3 may be adapted to a shape of the first edge area A4. For example, if the first central area A3 is in a square structure, the first edge area A4 is in a square ring structure. If the first central area A3 is in a circular structure, the first edge area A4 is in a circular ring structure. The second central area A5 and the second edge area A6 on the second light-emitting surface C2 are the same as the first central area A3 and the first edge area A4 on the first light-emitting surface C1, which are not repeated in the embodiments of the present application.

Further, the size of the first light-shielding material portion 34 in the first central area A3 is smaller than the size of the first light-shielding material portion 34 in the first edge area A4, and the size of the second light-shielding material portion 35 in the second central area A5 is smaller than the size of the second light-shielding material portion 35 in the second edge area A6, which indicates that the light-shielding layer 30 is prepared and formed by printing black light-shielding material.

Specifically, when printing the black light-shielding material, the black light-shielding material may infiltrate and diffuse along the side surface of the light-emitting element 20 to the light-emitting surface of the light-emitting element 20, and the black light-shielding material reaching the light-emitting surface of the first light-emitting element 21 may first reach the first edge area A4, and then diffuse from the first edge area A4 to the first center area A3, which results in the size of the first light-shielding material portion 34 in the first center area A3 being smaller than the size of the first light-shielding material portion 34 in the first edge area A4.

Considering that the light-shielding material in the edge area of the light-emitting surface is prone to flow to the periphery of the light-emitting element 20 than the light-shielding material in the center area, in the embodiments of the present application, the light-shielding layer 30 is formed by printing, and the structure of the first light-emitting element 21 itself or other structures of the periphery of the first light-emitting element 21 is adjusted, so that more light-shielding material on the first light-emitting surface C1 can flow to the periphery of the first light-emitting element 21, thereby further reducing the size of the first light-shielding material portion 34 and improving the corresponding light extraction efficiency of the first light-emitting element 21.

In some embodiments, as shown in FIG. 16, in the thickness direction Z of the array substrate 10, the size of the first light-shielding material portion 34 in the first edge area A4 is smaller than the size of the second light-shielding material portion 35 in the second edge area A6.

In the embodiments of the present application, due to the adjustment of the structure of the first light-emitting element 21 itself or other structures of the periphery of the first light-emitting element 21, more light-shielding materials in the first edge area A4 can flow to the periphery of the first light-emitting element 21, so that the light-shielding effect of the first light-shielding material portion 34 on the first light-emitting element 21 in the first edge area A4 is smaller than the light-shielding effect of the second light-shielding material portion 35 on the second light-emitting element 22 in the second edge area A6, which is conducive to reducing the shielding effect of the first light-shielding material portion 34 on the wide-angle light emitted by the first light-emitting element 21, improving the brightness of the display panel 100 under wide-angle display and display uniformity, and has strong practicality.

In some embodiments, the first light-emitting element 21 is used to emit red light, and the second light-emitting element 22 is used to emit blue light or green light.

Compared with the light-emitting element 20 for emitting blue light or green light, the light-emitting element 20 for emitting red light is more susceptible to the influence of the light-shielding material, resulting in a reduction in light extraction efficiency. In view of this, in the embodiments of the present application, the structure of the first light-emitting element 21 for emitting red light or other structures of the periphery thereof is adjusted, so as to reduce the influence of the light-shielding material on the light extraction efficiency of red light, which is conducive to improving the display uniformity and display effect.

Further, in some optional embodiments, a plurality of light-emitting elements 20 also include a third light-emitting element 23, the first light-emitting element 21 is used to emit red light, the second light-emitting element 22 is used to emit green light, and the third light-emitting element 23 is used to emit blue light.

In some embodiments, referring to FIG. 17, the display panel 100 further includes a transparent adhesive layer 50 disposed on one side of the light-shielding layer 30 facing away from the array substrate 10, and the transparent adhesive layer 50 includes a second surface M2 facing away from the array substrate 10, and the second surface M2 is parallel to the plane where the array substrate 10 is located.

The transparent adhesive layer 50 may be in a whole surface structure, and the transparent adhesive layer 50 can cover a plurality of light-emitting elements 20. The transparent adhesive layer 50 includes a transparent adhesive material. In the thickness direction Z of the array substrate 10, two sides of the transparent adhesive layer 50 may be bonded and fixed to different film layers respectively to improve the position reliability between different film layers.

The second surface M2 is a surface of the transparent adhesive layer 50 facing away from the array substrate 10, and the second surface M2 is parallel to the plane where the array substrate 10 is located, that is, the second surface M2 is in a flat structure. Considering that a surface of one side of the light-shielding layer 30 facing away from the array substrate 10 is not in a flat structure, in the embodiments of the present application, by adding a transparent adhesive layer 50 on one side of the light-shielding layer 30 facing away from the array substrate 10, and flattening the second surface M2 of the transparent adhesive layer 50, it is conducive to improving the bonding strengths of the transparent adhesive layer 50 and other film layers on one side of the transparent adhesive layer 50 facing away from the array substrate 10, and improving the structural reliability of the display panel 100.

In some embodiments, the display panel 100 also includes an inorganic layer 60 disposed on one side of the light-shielding layer 30 facing away from the array substrate 10.

Considering that the light-shielding material in the light-shielding layer 30 usually includes organic materials, and the water blocking effect corresponding to the organic materials is usually not good, in view of this, in the embodiments of the present application, by adding an inorganic layer 60 on one side of the light-shielding layer 30 facing away from the array substrate 10, the inorganic material in the inorganic layer 60 has a water vapor blocking effect, thereby improving the water blocking protection effect of the light-emitting element 20 and the array substrate 10, which has strong practicality.

It should be noted that, in addition to the film layer structure mentioned above, the display panel may also include other film layer structures. The specific film layer composition of the display panel is not limited in the embodiments of the present application. Optionally, the display panel may be a transparent display panel and include a cover plate 70 located on one side of the inorganic layer 60 facing away from the array substrate 10, and an anti-glare layer 80 located on one side of the cover plate 70 facing away from the array substrate 10, which can reduce the halo problem caused by the reflection of external light. Since it is a transparent display panel, it is likely to have a halo problem in general. By disposing the anti-glare layer 80, the halo degree can be reduced and the usage experience of the display panel can be improved.

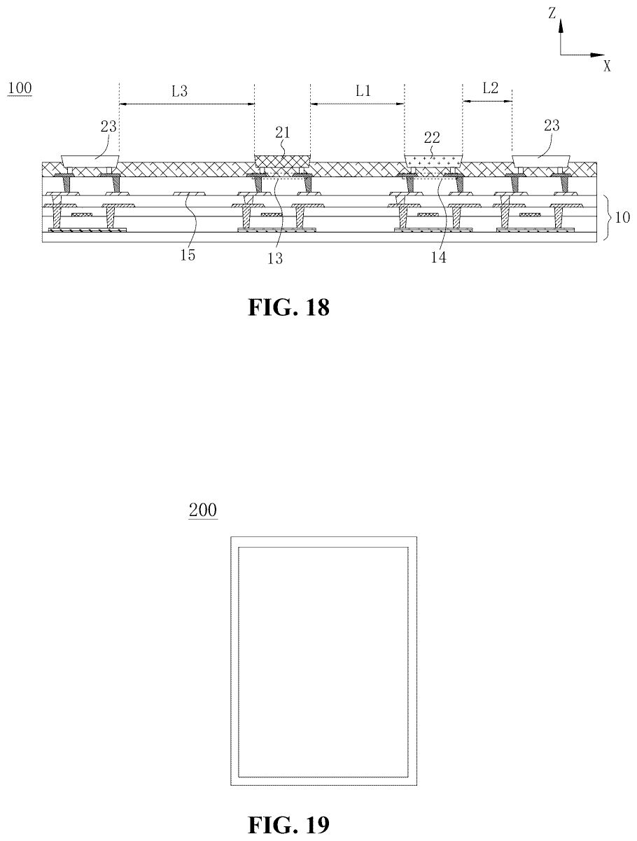

In the second aspect, referring to FIG. 18. An embodiment of the present application provides a display panel 100, the display panel 100 includes an array substrate 10, a light-emitting element 20 and a light-shielding layer 30. The light-emitting element 20 is located on one side of the array substrate 10 and is electrically connected to the array substrate 10. A plurality of light-emitting elements 20 include a first light-emitting element 21, a second light-emitting element 22 and a third light-emitting element 23 arranged adjacently one another. The light-shielding layer 30 is arranged on one side of the array substrate 10, and is at least partially located between adjacent of the light-emitting elements 20, where a distance between the first light-emitting element 21 and the second light-emitting element 22 adjacent to each other is greater than a distance between the second light-emitting element 22 and the third light-emitting element 23 adjacent to each other.

The plurality of light-emitting elements 20 include the first light-emitting element 21, the second light-emitting element 22 and the third light-emitting element 23 arranged adjacently one another in sequence, and the first light-emitting element 21, the second light-emitting element 22 and the third light-emitting element 23 may be different light-emitting elements 20 used to constitute the same repeating unit F, where the luminous colors of any two of the first light-emitting element 21, the second light-emitting element 22 and the third light-emitting element 23 may be the same, or may be different. Optionally, the luminous colors corresponding to the first light-emitting element 21, the second light-emitting element 22 and the third light-emitting element 23 are all different.

It should be noted that the specific arrangement of the first light-emitting element 21, the second light-emitting element 22 and the third light-emitting element 23 arranged adjacently one another is not limited in the embodiments of the present application. Exemplarily, the first light-emitting element 21, the second light-emitting element 22 and the third light-emitting element 23 may be arranged adjacently one another in sequence along the first direction X, or the first light-emitting element 21 and the second light-emitting element 22 may be arranged adjacent to each other along the first direction X, and the second light-emitting element 22 and the third light-emitting element 23 may be arranged adjacent to each other along the second direction Y.

Further, in the embodiments of the present application, the distance L1 between the first light-emitting element 21 and the second light-emitting element 22 adjacent to each other is also set to be greater than the distance L2 between the second light-emitting element 22 and the third light-emitting element 23 adjacent to each other.

Thus, there can be a larger space between the first light-emitting element 21 and the second light-emitting element 22 for accommodating the light-shielding material. On this basis, it is more likely that the light-shielding material located on the first light-emitting element 21 can flow between the first light-emitting element 21 and the second light-emitting element 22, thereby improving the light extraction efficiency corresponding to the first light-emitting element 21, and reducing the brightness differences of the first light-emitting element 21 and other light-emitting elements 20, which are conducive to improving the display uniformity and display effect.

In the third aspect, referring to FIG. 19. An embodiment of the present application provides a display apparatus 200, and the display apparatus 200 includes a display panel in any of the aforementioned embodiments, where the display apparatus 200 includes but is not limited to a mobile phone, a tablet and a vehicle-mounted display device.

It should be noted that the display apparatus 200 provided in the embodiments of the present application has the beneficial effects of the display panel in any of the aforementioned embodiments. Referring to the aforementioned description of the beneficial effects of the display panel for details, which is not limited in the embodiments of the present application.

Although the embodiments disclosed in the present application are as above, the contents described are only embodiments adopted for the convenience of understanding the present application, and are not used to limit the present application. Any technician in the technical field to which the present application belongs can make any modifications and changes in the form and details of the implementation without departing from the gist and scope disclosed in the present application, but the scope of protection of the present application shall still be subject to the scope defined in the attached claims.

The above are only specific embodiments of the present application. The technicians in the relevant field can clearly understand that for the convenience and simplicity of description, the replacement of other connection methods described above may refer to the corresponding process in the aforementioned method embodiments, and are not repeated here. It should be understood that the scope of protection of the present application is not limited to this. Any technician familiar with the technical field can easily think of various equivalent modifications or replacements within the technical scope disclosed in the present application, and these modifications or replacements should be covered within the scope of protection of the present application.

What is claimed is:

1. A display panel, comprising:
an array substrate;
a light-emitting element located on a side of the array substrate and electrically connected to the array substrate, wherein a plurality of the light-emitting elements comprise a first light-emitting element and a second light-emitting element with different colors, the first light-emitting element having a first light-emitting surface facing away from the array substrate, and the second light-emitting element having a second light-emitting surface facing away from the array substrate; and
a light-shielding layer arranged on a side of the array substrate, wherein in a direction parallel to a plane where the array substrate is located, the light-shielding layer comprises a first light-shielding portion arranged adjacent to the first light-emitting element, and a second light-shielding portion arranged adjacent to the second light-emitting element;
wherein in a thickness direction of the array substrate, a distance between a plane where the first light-emitting surface is located and the first light-shielding portion is greater than a distance between the second light-emitting surface and the second light-shielding portion.

2. The display panel according to claim 1, wherein the plane where the first light-emitting surface is located is located on a side of a plane where the second light-emitting surface is located facing away from the array substrate.

3. The display panel according to claim 2, wherein the first light-emitting element comprises a first epitaxial structure and a first electrode structure, and the second light-emitting element comprises a second epitaxial structure and a second electrode structure;
wherein in the thickness direction of the array substrate, a size of the first epitaxial structure is larger than a size of the second epitaxial structure; or, in the thickness direction of the array substrate, a size of the first electrode structure is larger than a size of the second electrode structure.

4. The display panel according to claim 2, wherein the first light-emitting element comprises a first light-emitting body and a first light-transmitting portion located on a side of the first light-emitting body facing away from the array substrate.

5. The display panel according to claim 4, wherein the second light-emitting element comprises a second light-emitting body and a second light-transmitting portion located on a side of the second light-emitting body facing away from the array substrate;
wherein in the thickness direction of the array substrate, the size of the first light-transmitting portion is larger than a size of the second light-transmitting portion.

6. The display panel according to claim 2, wherein the array substrate has a first surface and a convex portion protruding from the first surface, the light-emitting element is located on a side of the first surface, and along the thickness direction of the array substrate, the first light-emitting element overlaps the convex portion; or,
the array substrate has a first surface and a concave portion that is concave inwardly with respect to the first surface, the light-emitting element is located on a side of the first surface, and along the thickness direction of the array substrate, the second light-emitting element overlaps the concave portion.

7. The display panel according to claim 2, wherein the array substrate comprises a bonding pad structure and a pixel circuit, the bonding pad structure is electrically connected to the light-emitting element and the pixel circuit each, and a plurality of the bonding pad structures comprises a first bonding pad electrically connected to the first light-emitting element, and a second bonding pad electrically connected to the second light-emitting element;
wherein along the thickness direction of the array substrate, the first bonding pad overlaps the first light-emitting element, the second bonding pad overlaps the second light-emitting element, and a size of the first bonding pad is larger than a size of the second bonding pad.

8. The display panel according to claim 1, wherein a plurality of the light-emitting elements further comprise a third light-emitting element having a color different from those of the first light-emitting element and the second light-emitting element, and the third light-emitting element has a third light-emitting surface facing away from the array substrate;
the light-shielding portion comprises a third light-shielding portion arranged adjacent to the third light-emitting element, and in the thickness direction of the array substrate, a distance between the plane where the first light-emitting surface is located and the first light-shielding portion is greater than a distance between the third light-emitting surface and the third light-shielding portion.

9. The display panel according to claim 1, wherein a plurality of the light-emitting elements form a repeating unit, a plurality of the repeating units are arranged repeatedly, and the repeating unit comprises the first light-emitting element, the second light-emitting element, and the third light-emitting element arranged adjacently one another in sequence;
wherein a distance between the first light-emitting element and the second light-emitting element adjacent to each other is greater than a distance between the second light-emitting element and the third light-emitting element adjacent to each other.

10. The display panel according to claim 9, wherein the first light-emitting element in one of the repeating units is arranged adjacent to the third light-emitting element in another one of the repeating units;
wherein a distance between the first light-emitting element and the third light-emitting element adjacent to each other is greater than a distance between the second light-emitting element and the third light-emitting element adjacent to each other.

11. The display panel according to claim 10, wherein the array substrate comprises a first signal line, and along the thickness direction of the array substrate, the first signal line does not overlap the repeating unit, and along an arrangement direction of the repeating unit, the first signal line is located between adjacent of the repeating units.

12. The display panel according to claim 10, wherein in adjacent of the repeating units, a distance between the first light-emitting element and the third light-emitting element adjacent to each other is greater than a distance between the first light-emitting element and the second light-emitting element adjacent to each other.

13. The display panel according to claim 9, wherein the display panel has a first area and a second area, and a distance between a center of the first area and a center of the display panel is smaller than a distance between a center of the second area and the center of the display panel;
wherein a distance between the first light-emitting element and the second light-emitting element adjacent to each other in the first area is greater than a distance between the first light-emitting element and the second light-emitting element in the second area.

14. The display panel according to claim 1, wherein the light-shielding layer comprises a second light-shielding material portion located on a side of the second light-emitting element facing away from the array substrate;
wherein the light-shielding layer comprises a first light-shielding material portion located on a side of the first light-emitting element facing away from the array substrate, and in the thickness direction of the array substrate, a size of the first light-shielding material portion is smaller than a size of the second light-shielding material portion.

15. The display panel according to claim 14, wherein the first light-emitting surface has a first central area and a first edge area located on a periphery of the first central area, and in the thickness direction of the array substrate, a size of the first light-shielding material portion in the first central area is smaller than a size of the first light-shielding material portion in the first edge area; and
the second light-emitting surface has a second central area and a second edge area located on a periphery of the second central area, and in the thickness direction of the array substrate, a size of the second light-shielding material portion in the second central area is smaller than a size of the second light-shielding material portion in the second edge area.

16. The display panel according to claim 15, wherein in the thickness direction of the array substrate, the size of the first light-shielding material portion in the first edge area is smaller than the size of the second light-shielding material portion in the second edge area.

17. The display panel according to claim 1, wherein the first light-emitting element is configured to emit a red light, and the second light-emitting element is configured to emit a blue light or a green light.

18. The display panel according to claim 1, wherein the display panel further comprises a transparent adhesive layer disposed on a side of the light-shielding layer facing away from the array substrate, the transparent adhesive layer comprises a second surface facing away from the array substrate, and the second surface is parallel to the plane where the array substrate is located; or,
wherein the display panel further comprises an inorganic layer disposed on a side of the light-shielding layer facing away from the array substrate.

19. A display panel, comprising:
an array substrate;
a light-emitting element located on a side of the array substrate and electrically connected to the array substrate, wherein a plurality of the light-emitting elements comprises a first light-emitting element, a second light-emitting element and a third light-emitting element arranged adjacently one another; and
a light-shielding layer arranged on a side of the array substrate and at least partially located between adjacent of the light-emitting elements;
wherein a distance between the first light-emitting element and the second light-emitting element adjacent to each other is greater than a distance between the second light-emitting element and the third light-emitting element adjacent to each other.

20. A display apparatus, comprising a display panel comprising:
an array substrate;
a light-emitting element located on a side of the array substrate and electrically connected to the array substrate, wherein a plurality of the light-emitting elements comprise a first light-emitting element and a second light-emitting element with different colors, the first light-emitting element having a first light-emitting surface facing away from the array substrate, and the second light-emitting element having a second light-emitting surface facing away from the array substrate; and
a light-shielding layer arranged on a side of the array substrate, wherein in a direction parallel to a plane where the array substrate is located, the light-shielding layer comprises a first light-shielding portion arranged adjacent to the first light-emitting element, and a second light-shielding portion arranged adjacent to the second light-emitting element;
wherein in a thickness direction of the array substrate, a distance between a plane where the first light-emitting surface is located and the first light-shielding portion is greater than a distance between the second light-emitting surface and the second light-shielding portion.
